(19) United States
(12) Patent Application Publication
(10) Pub. No.: US 2017/0070225 A1
(43) Pub. Date: Mar. 9, 2017

(54) POWER GATING DEVICES AND METHODS

(71) Applicant: QUALCOMM Incorporated, San Diego, CA (US)

(72) Inventors: Jung Pill KIM, San Diego, CA (US); Sungryul KIM, San Diego, CA (US); Taehyun KIM, San Diego, CA (US)

(21) Appl. No.: 14/847,387

(22) Filed: Sep. 8, 2015

(51) Int. Cl. H03K 17/687; H03K 17/693

(52) U.S. Cl. CPC H03K 17/6871; H03K 17/693

(57) ABSTRACT

A device includes a first power rail and a second power rail. A second voltage of the second power rail is derived from a first voltage of the first power rail. The device includes a power gating circuit that includes a switching device connected between the first power rail and the second power rail. The power gating circuit further includes a clamping diode connected in parallel to the switching device between the first power rail and the second power rail. The device further includes a logic circuit including a first inverter and a second inverter. The first inverter includes a first transistor and the second inverter includes a first transistor. A source/drain terminal of the first transistor of the first inverter is directly coupled to the first power rail, and a source/drain terminal of the first transistor of the second inverter is directly coupled to the second power rail.

### I. FIELD

The present disclosure is generally related to power gating devices and methods.

### II. DESCRIPTION OF RELATED ART

Advances in technology have resulted in smaller and more powerful computing devices. For example, there currently exist a variety of portable personal computing devices, including wireless telephones, such as mobile and smart phones, tablets and laptop computers, that are small, lightweight, and easily carried by users. These devices can communicate voice and data packets over wireless networks. Further, many such devices incorporate additional functionality, such as a digital still camera, a digital video camera, a digital recorder, and an audio file player. Also, such devices can process executable instructions, including software applications, such as a web browser application, that can be used to access the Internet. As such, these devices can include significant computing capabilities.

Logic (e.g., decoders) in chips (e.g., memory chips) in these devices may include many transistors and may occupy large portions of the chip area. The transistors may experience leakage (e.g., subthreshold leakage) during operation in a power saving mode (e.g., a standby mode). Power gating the logic from its power supply or ground rails during the power saving mode may reduce leakage. However, power gating the logic using conventional power gating schemes causes voltage to the logic to float, resulting in unknown transistor states or initial conditions (e.g., at a transition to a normal mode).

### III. SUMMARY

In a particular embodiment, a device is disclosed. The device includes a first power rail and a second power rail. A second voltage of the second power rail is derived from a first voltage of the first power rail. The device includes a power gating circuit. The power gating circuit includes a switching device connected between the first power rail and the second power rail. The power gating circuit further includes a clamping diode connected in parallel to the switching device between the first power rail and the second power rail. The device further includes a logic circuit including a first inverter and a second inverter. The first inverter includes a first transistor of the first inverter, and the second inverter includes a first transistor of the second inverter. A source/drain terminal of the first transistor of the first inverter is directly coupled to the first power rail, and a source/drain terminal of the first transistor of the second inverter is directly coupled to the second power rail.

In a particular embodiment, a decoder device is disclosed that includes a unit address decoder. The decoder device also includes a power gating circuit. The power gating circuit includes a switching device connected between the unit address decoder and a voltage source. The power gating circuit further includes a clamping diode connected in parallel to the switching device between the unit address decoder and the voltage source.

In a particular embodiment, a method of power gating a circuit includes applying a first voltage to a source/drain terminal of a first transistor of a first inverter via a first power rail directly coupled to the source/drain terminal of the first transistor of the first inverter. The method further includes applying, via a second power rail directly coupled to a source/drain terminal of a first transistor of a second inverter, a second voltage to the source/drain terminal of the first transistor of the second inverter by clamping a voltage at the second power rail to the second voltage using a clamping diode connected in parallel between the first power rail and the second power rail. The second voltage is derived from a first voltage applied to the first power rail.

In a particular embodiment, a device is disclosed that includes a first ground rail and a second ground rail. A second voltage of the second ground rail is derived from a first voltage of the first ground rail. The device includes a power gating circuit. The power gating circuit includes a switching device connected between the first ground rail and the second ground rail. The power gating circuit further includes a clamping diode connected in parallel to the switching device between the first ground rail and the second ground rail. The device further includes a logic circuit including a first inverter including a transistor and a second inverter including a transistor. A source/drain terminal of the transistor of the first inverter is directly coupled to the second ground rail, and a source/drain terminal of the transistor of the second inverter is directly coupled to the first ground rail.

One particular advantage provided by at least one of the disclosed embodiments is that a gate to source voltage resulting at least in part from applying the second voltage to the drain/source terminal may reduce sub-threshold leakage current. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a block diagram of a particular illustrative embodiment of a device including power gating circuits and inverters interleaved between a first power rail and a second power rail and between a first ground rail and a second ground rail;

FIG. 2 is a block diagram of a particular illustrative embodiment of a decoder device including a unit address decoder, power gating circuits, and inverters interleaved between a first power rail and a second power rail and between a first ground rail and a second ground rail;

FIG. 3 is a block diagram illustrating a memory device that includes power gating circuits, where each of the power gating circuits power gates multiple unit address decoders;

FIG. 4 is a flow chart of a particular illustrative embodiment of a method of power gating a circuit; and

FIG. 5 is a block diagram of portable device including a power gating device.

### V. DETAILED DESCRIPTION

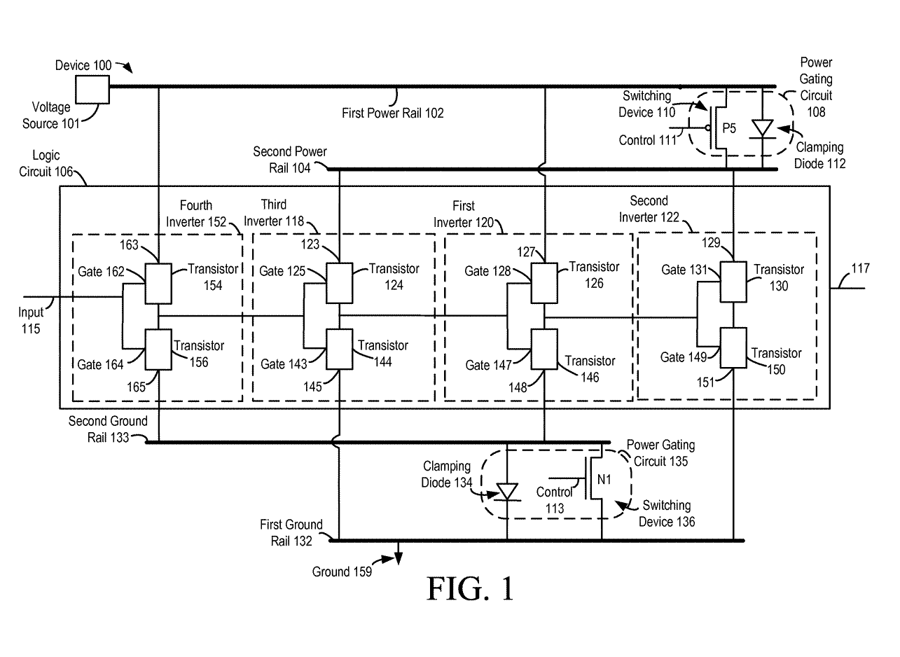

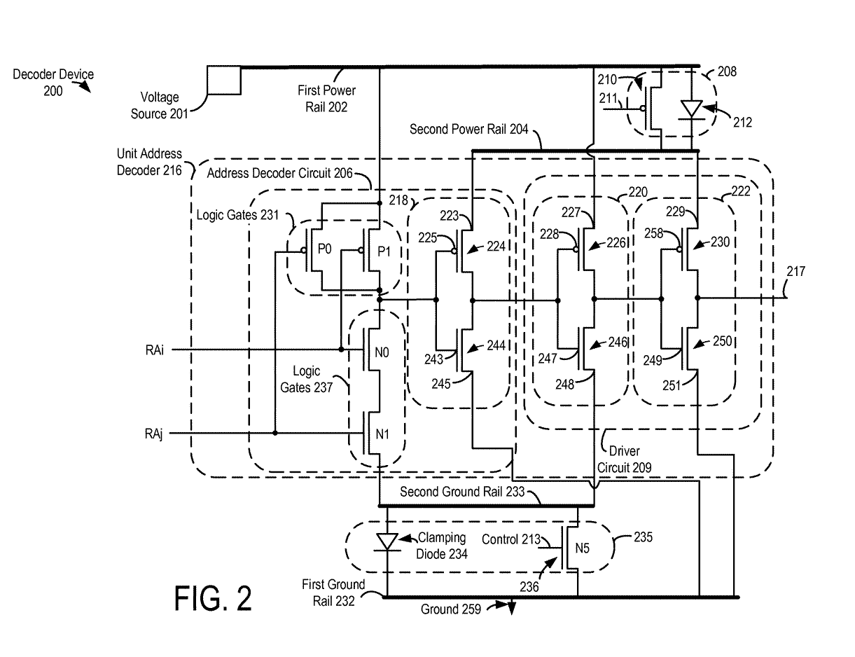

Referring to FIG. 1, a particular illustrative embodiment of a device is disclosed and generally designated 100. The device 100 includes a logic circuit 106 coupled to a first power rail 102, a second power rail 104, a first ground rail 132, and a second ground rail 133. The logic circuit 106 may include a unit address decoder, such as a unit address decoder 216 of FIG. 2.

The first power rail 102 may correspond to or be referred to as a real, main, or fixed power rail. A voltage (e.g., a “first voltage”) of the first power rail 102 may correspond to a voltage of a voltage source 101 coupled to the first power rail 102. In some examples, the first power rail 102 is directly coupled to the voltage source 101. A voltage (e.g., a “second voltage”) of the second power rail 104 may be derived from the first voltage of the first power rail 102 as described in more detail below. As described in more detail below, in some operating modes or conditions, the second voltage may correspond to the first voltage, whereas in other operating modes or conditions, the second voltage may be different than (e.g., less than) the first voltage.

The device 100 includes a first power gating circuit 108 including a switching device 110 connected between (e.g., electrically between) the first power rail 102 and the second power rail 104. In some examples, the switching device 110 includes a p-type metal oxide semiconductor (PMOS) transistor. The first power gating circuit 108 further includes a clamping diode 112 connected in parallel (e.g., electrical parallel) to the switching device 110 between (e.g., electrically between) the first power rail 102 and the second power rail 104. For example, an input of the clamping diode 112 and a source terminal or a drain terminal of the switching device 110 may be connected to the first power rail 102, and a source or a drain terminal of the switching device 110 and an output of the clamping diode 112 may be connected to the second power rail 104. In some examples, the clamping diode 112 may correspond to or may include a PMOS transistor (e.g., a “diode-connected PMOS transistor”). In some examples, the diode-connected PMOS transistor may include a drain terminal and a gate terminal coupled to the second power rail 104 and a source terminal coupled to the first power rail 102.

In some examples, such as when the logic circuit 106 is in a first operating mode (e.g., a non-power saving mode), the switching device 110 may be closed and the first voltage from the first power rail 102 may be supplied (e.g., across the switching device 110) to the second power rail 104 such that the second voltage of the second power rail 104 corresponds to (e.g., is substantially equal to) the first voltage of the first power rail 102. In other examples, such as when the logic circuit 106 is in a second operating mode (e.g., a power saving mode), the switching device 110 may be open and only a portion of the first voltage from the first power rail 102 is supplied to the second power rail 104 such that the second voltage of the second power rail 104 corresponds to a voltage that is different (e.g., substantially different) than (e.g., less than) the first voltage of the first power rail 102. In some examples, the second voltage may correspond to the first voltage (e.g., Vdd) from the first power rail 102 minus a threshold voltage of the clamping diode 112.

For example, during operation in the non-power saving mode, the switching device 110 may be closed, thereby short-circuiting the first power rail 102 to the second power rail 104 (causing the first voltage from the first power rail 102 to be applied across the switching device 110 to the second power rail 104). Thus, the second voltage of the second power rail 104 may correspond to (e.g., may be substantially equal to) the first voltage of the first power rail 102 during the non-power saving mode. During the power saving mode, a signal that opens (e.g., turns off) the switching device 110 may be applied to the switching device 110 via a control 111. Opening the switching device 110 may cause leakage current to discharge the voltage at the second power rail 104 to a voltage (e.g., the second voltage) that causes the clamping diode 112 to turn on, thereby clamping the voltage at the second power rail 104 at a different (e.g., a substantially different) voltage than the first voltage. To illustrate, the first voltage may correspond to 1.5V, and the threshold voltage of the clamping diode 112 may correspond to 0.2V. In this example, when the switching device 110 is open (e.g., off), the second power rail 104 may discharge to 1.3V, at which point the clamping diode 112 may turn on and may clamp the second voltage of the second power rail 104 at 1.3V (e.g., 1.5V-0.2V=1.3 V).

As described above, in some examples, the switching device 110 may correspond to or may include a PMOS transistor, and the clamping diode 112 may correspond to or may include the diode-connected PMOS transistor. In these examples, during the power saving mode, the switching device 110 is off and in a floating state, which causes the second power rail 104 to discharge (e.g., causing the voltage at the second power rail 104 to drop and causing a potential difference between the first power rail 102 and the second power rail 104 to increase). The voltage at the second power rail 104 may drop until the voltage difference between the first power rail 102 and the second power rail 104 (e.g., the source-to-drain voltage V_{SD} of the diode-connected PMOS transistor) corresponds to the threshold voltage of the diode-connected PMOS transistor. When the V_{SD} of the diode-connected PMOS transistor corresponds to the threshold voltage of the diode-connected PMOS transistor, the diode-connected PMOS transistor may turn on, causing the second voltage of the second power rail 104 to correspond to the first voltage of the first power rail 102 minus the threshold voltage of the diode-connected PMOS transistor.

Thus, the second voltage of the second power rail 104 may be derived from the first voltage of the first power rail 102 and may vary based on the first power gating circuit 108 (e.g., based on whether the switching device 110 is open or closed), which may be controlled (e.g., by the control 111) based on an operating mode of the logic circuit 106.

The device 100 includes a first ground rail 132 and a second ground rail 133. The first ground rail 132 may correspond to or be referred to as a real, main, or fixed ground rail. In some examples, a voltage (e.g., a “third voltage”) of the first ground rail 132 may correspond to ground. In some examples, the first ground rail 132 is directly coupled to ground 159. A voltage (e.g., a “fourth voltage”) of the second ground rail 133 may be derived from the third voltage as described in more detail below. As described in more detail below, in some operating conditions, such as when the logic circuit 106 is operating in the non-power saving mode, the fourth voltage may correspond to the third voltage, whereas in other operating conditions, the fourth voltage may be different than (e.g., greater than) the third voltage.

The device 100 includes a second power gating circuit 135 including a switching device 136 connected between (e.g., electrically between) the first ground rail 132 and the second ground rail 133. In some examples, the switching device 136 includes an n-type metal oxide semiconductor (NMOS) transistor. The second power gating circuit 135 further includes a clamping diode 134 connected in parallel (e.g., electrical parallel) to the switching device 136 between (e.g., electrically between) the first ground rail 132 and the second ground rail 133. For example, an input of the clamping diode 134 and a source terminal or a drain terminal of the switching device 136 may be connected to the first ground rail 132, and a source or a drain terminal of the switching device 136 and an output of the clamping diode 134 may be connected to the second ground rail 133. In some examples, the clamping diode 134 may correspond to or may include an NMOS transistor (e.g., a “diode-connected NMOS transistor”). In some examples, the diode-connected NMOS transistor may include a drain terminal and a gate terminal coupled to the second ground rail 133 and a source terminal coupled to the first ground rail 132.

In some examples, such as when the logic circuit 106 is in the first operating mode (e.g., a non-power saving mode), the switching device 136 may be closed and the third voltage from the first ground rail 132 may be supplied (e.g., across the switching device 136) to the second ground rail 133 such that the fourth voltage of the second ground rail 133 corresponds to (e.g., is substantially equal to) the third voltage of the first ground rail 132. In other examples, such as when the logic circuit 106 is in the second operating mode, the switching device 136 may be open and the fourth voltage of the second ground rail 133 may correspond to a voltage that is different (e.g., substantially different) than (e.g., greater than) the third voltage of the first ground rail 132, as described in more detail below. In some examples, the fourth voltage may correspond to the third voltage (e.g., Vss) from the first ground rail 132 plus a threshold voltage of the clamping diode 134.

For example, during operation in the non-power saving mode, the switching device 136 may be closed, thereby short-circuiting the first ground rail 132 to the second ground rail 133 (causing the third voltage from the first ground rail 132 to be applied across the switching device 136 to the second ground rail 133). Thus, the fourth voltage of the second ground rail 133 may correspond to (e.g., may be substantially equal to) the first voltage of the first ground rail 132 during the non-power saving mode. During the power saving mode, a signal that opens (e.g., turns off) the switching device 136 may be applied to the switching device 136 via a control 113. Opening the switching device 136 may cause leakage current to charge the voltage at the second ground rail 133 to a voltage (e.g., the fourth voltage) that causes the clamping diode 134 to turn on, thereby clamping the voltage at the second ground rail 133 to a different (e.g., a substantially different) voltage than the third voltage. To illustrate, the third voltage may correspond to 0V, and the threshold voltage of the clamping diode 134 may correspond to 0.2V. In this example, when the switching device 136 is open (e.g., off), the second ground rail 133 may charge to 0.2V, at which point the clamping diode 134 may turn on and may clamp the fourth voltage of the second ground rail 133 to 0.2V (e.g., 0V+0.2V=0.2 V).

As described above, in some examples, the switching device 136 may correspond to or may include an NMOS transistor and the clamping diode 134 may correspond to or may include the diode-connected NMOS transistor. In these examples, during the power saving mode, the switching device 136 is off and in a floating state, which causes the second ground rail 133 to charge (e.g., causing the voltage at the second ground rail 133 to increase and causing a potential difference between the first ground rail 132 and the second ground rail 133 to increase). The voltage at the second ground rail 133 may increase until the voltage difference between the first ground rail 132 and the second ground rail 133 (e.g., the drain-to-source voltage V_{DS} of the diode-connected NMOS transistor) corresponds to the threshold voltage of the diode-connected NMOS transistor. When the V_{DS} of the diode-connected NMOS transistor corresponds to the threshold voltage of the diode-connected NMOS transistor, the diode-connected NMOS transistor may turn on, causing the fourth voltage of the second ground rail 133 to correspond to the third voltage of the first ground rail 132 minus the threshold voltage of the diode-connected NMOS transistor.

Thus, the fourth voltage of the second ground rail 133 may be derived from the third voltage of the first ground rail 132 and may vary based on the second power gating circuit 135 (e.g., based on whether the switching device 136 is open or closed), which may be controlled (e.g., by the control 113) based on an operating mode of the logic circuit 106.

The logic circuit 106 may include an input 115, a first inverter 120, a second inverter 122, a third inverter 118, a fourth inverter 152, and an output 117. The first inverter 120 may include a first transistor 126 and a second transistor 146. The second inverter 122 may include a first transistor 130 and a second transistor 150. The third inverter 118 may include a first transistor 124 and a second transistor 144. The fourth inverter 152 may include a first transistor 154 and a second transistor 156. In some examples, the first transistor 126 of the first inverter 120, the first transistor 130 of the second inverter 122, the first transistor 124 of the third inverter 118, the first transistor 154 of the fourth inverter 152, or a combination thereof, include a PMOS transistor. Additionally or alternatively, in some examples, the second transistor 146 of the first inverter 120, the second transistor 150 of the second inverter 122, the second transistor 144 of the third inverter 118, the second transistor 156 of the fourth inverter 152, or a combination thereof, include an NMOS transistor. Though the logic circuit 106 is illustrated as including an even number of inverters, the logic circuit 106 may include an odd number of inverters.

A terminal 127 (e.g., a source terminal or a drain terminal) of the first transistor 126 of the first inverter 120 may be coupled (e.g., directly) to the first power rail 102. Additionally or alternatively, a terminal 129 (e.g., a source terminal or a drain terminal) of the first transistor 130 of the second inverter 122 may be coupled (e.g., directly) to the second power rail 104. Additionally or alternatively, a terminal 123 (e.g., a source terminal or a drain terminal) of the first transistor 124 of the third inverter 118 may be coupled (e.g., directly) to the second power rail 104. Additionally or alternatively, a terminal 163 (e.g., a source terminal or a drain terminal) of the first transistor 154 of the fourth inverter 152 may be coupled (e.g., directly) to the first power rail 102.

Additionally or alternatively, a terminal 148 (e.g., a source terminal or a drain terminal) of the second transistor 146 of the first inverter 120 may be coupled (e.g., directly) to the second ground rail 133. Additionally or alternatively, a terminal 151 (e.g., a source terminal or a drain terminal) of the second transistor 150 of the second inverter 122 may be coupled (e.g., directly) to the first ground rail 132. Additionally or alternatively, a terminal 145 (e.g., a source terminal or a drain terminal) of the second transistor 144 of the third inverter 118 may be coupled (e.g., directly) to the first ground rail 132. Additionally or alternatively, a terminal 165 (e.g., a source terminal or a drain terminal) of the second transistor 156 of the fourth inverter 152 may be coupled (e.g., directly) to the second ground rail 133.

During operation in the power saving mode, the terminal 123 of the first transistor 124 of third inverter 118 may receive the second voltage from the second power rail 104 and the terminal 145 of the second transistor 144 of the third inverter 118 may receive a third (e.g., ground) voltage from the first ground rail 132. During operation in the power saving mode, a low (e.g., a logic low) input signal (e.g., ground) may be provided to the input 115 (e.g., to gate terminals 162 and 164 of the fourth inverter 152). Alternatively, as described above, the logic circuit 106 may include an odd number of inverters and a high (e.g., a logic high) input signal may be provided to the input 115.

Application of the low input signal to the input of the fourth inverter 152 while the first voltage is applied to the terminal 163 of the first transistor 154 of the fourth inverter 152 may cause the first transistor 154 to turn on. For example, the first transistor 154 of the fourth inverter 152 may correspond to a PMOS transistor, and application of the low signal to the gate terminal 162 of the first transistor 154 while the first voltage is applied (e.g., via the first power rail 102) to the terminal 163 of the first transistor 154 may turn on the first transistor 154, causing the first voltage from the first power rail 102 to be applied to the input of the third inverter 118.

Application of the first voltage to the input of the third inverter 118 while the third voltage (e.g., ground) is applied to the terminal 145 of the second transistor 144 of the third inverter 118 may cause the second transistor 144 to turn on. For example, the second transistor 144 of the third inverter 118 may correspond to an NMOS transistor, and application of the voltage corresponding to the first voltage to the gate terminal 143 of the second transistor 144 while the third voltage is applied (e.g., via the first ground rail 132) to the terminal 145 of the second transistor 144 may turn on the second transistor 144.

Additionally or alternatively, application of the voltage corresponding to the first voltage to the input of the third inverter 118 while the switching device 110 is off and the second voltage (that is different than the first voltage as described above) is being applied to the terminal 123 of the first transistor 124 of the third inverter 118 may result in a non-zero (e.g., negative) source to gate voltage (V_{SG}) for the first transistor 124 that is not sufficient to turn on the first transistor 124 (e.g., the first transistor 124 may be off). The resulting non-zero (e.g., negative) V_{SG} may reduce (compared to a positive V_{SG} or a V_{SG} of 0V) leakage current through the first transistor 124 of the third inverter 118 while the first transistor 124 is off. For example, the first transistor 124 of the third inverter 118 may correspond to a PMOS transistor, and application of the first voltage (e.g., 1.5V) to the gate terminal 125 of the first transistor 124 while the second voltage (e.g., 1.3V) is applied to the terminal 123 of the first transistor 124 may turn off the first transistor 124 and may result in a non-zero (e.g., negative) V_{SG} for the first transistor 124 that corresponds to the second voltage minus the first voltage (e.g., 1.3V-1.5V=−0.2V). The resulting non-zero (e.g., negative) V_{SG} (e.g., the V_{SG} of −0.2V) may reduce (e.g., compared to a positive V_{SG} or a V_{SG} of 0V) leakage current through the first transistor 124 of the third inverter 118 while the first transistor 124 is off Thus, the first power gating circuit 108 may reduce standby leakage current through the first transistor 124 of the third inverter 118.

During operation in the power saving mode, the terminal 127 of the first transistor 126 of the first inverter 120 may receive the first voltage from the first power rail 102, and the terminal 148 of the second transistor 146 of the first inverter 120 may receive the fourth voltage (that is different than the third voltage as described above) from the second ground rail 133. Turning off the first transistor 124 of the third inverter 118 and turning on the second transistor 144 of the third inverter 118 as described above may cause an output of the third inverter 118 to correspond to the third voltage (e.g., the output of the third inverter 118 may correspond to ground). Thus, a voltage corresponding to the third voltage (e.g., to ground) may be applied to the input of the first inverter 120 (e.g., ground voltage may be applied to gate terminals 128 and 147).

Application of the voltage corresponding to the third voltage (e.g., ground) to the input of the first inverter 120 while the first voltage from the first power rail 102 is applied to the terminal 127 of the first transistor 126 of the first inverter 120 may turn on the first transistor 126. For example, the first transistor 126 of the first inverter 120 may correspond to a PMOS transistor, and application of the voltage (e.g., ground) corresponding to the third voltage (from an output of the third inverter 118) to the gate terminal 128 of the first transistor 126 while the first voltage (e.g., 1.5V) is being applied to the terminal 127 of the first transistor 126 may turn on the first transistor 126.

Application of the voltage corresponding to the third voltage to the input of the first inverter 120 while the switching device 136 is off and while the fourth voltage (that is substantially different than the third voltage) is being applied to the terminal 148 of the second transistor 146 of the first inverter 120 may prevent the second transistor 146 from turning on and may result in a non-zero (e.g., a negative) gate to source voltage (V_{GS}) for the second transistor 146. The resulting non-zero (e.g., negative) V_{GS} may reduce (compared to a positive V_{GS} or a V_{GS} of 0V) leakage current through the second transistor 146 of the first inverter 120 while the second transistor 146 is off. For example, the second transistor 146 of the first inverter 120 may correspond to an NMOS transistor, and application of the voltage (e.g., ground) corresponding to the third voltage (from an output of the third inverter 118) to the gate terminal 147 of the second transistor 146 while the fourth voltage (e.g., 0.2V) that is substantially different than the third voltage may prevent the second transistor 146 from turning on and may result in a V_{GS} of −0.2V (e.g., 0V−0.2V=−0.2V) for the second transistor 146. The non-zero (e.g., negative) V_{GS} (e.g., the V_{GS} of −0.2V) of the second transistor 146 of the first inverter 120 may reduce (compared to a positive V_{GS} or a V_{GS} of 0V) leakage current through the second transistor 146 while the second transistor 146 is off Thus, the second power gating circuit 135 may reduce standby leakage current through the second transistor 146 of the first inverter 120. Additionally, because the first transistor 126 is turned on and the second transistor 146 is turned off, the first inverter 120 may output (to the second inverter 122) the first voltage (passed from the first power rail 102 through the first transistor 126).

During operation in the power saving mode, the terminal 129 of the first transistor 130 of the second inverter 122 may receive the second voltage (that is different than the first voltage as described above) from the second power rail 104, and the terminal 151 of the second transistor 150 of the second inverter 122 may receive the third voltage (e.g., ground) from the first ground rail 132. Turning on the first transistor 126 of the first inverter 120 and turning off the second transistor 146 of the first inverter 120 as described above may cause an output of the first inverter 120 to correspond to the first voltage. Thus, the first voltage may be applied to the input of the second inverter 122 (e.g., may be applied to gate terminals 131 and 149).

Application of the first voltage to the input of the second inverter 122 while the third voltage from the first ground rail 132 is applied to the terminal 151 of the second transistor 150 of the second inverter 122 may turn on the second transistor 150. For example, the second transistor 150 of the second inverter 122 may correspond to an NMOS transistor, and application of the first voltage to the gate terminal 149 of the second transistor 150 while the third voltage (e.g., 0V) is being applied to the terminal 151 of the second transistor 150 may turn on the second transistor 150.

Application of the first voltage to the input of the second inverter 122 while the second voltage (that is different than the first voltage as described above) is being applied to the terminal 129 of the first transistor 130 of the second inverter 122 may turn off the first transistor 130 and may result in a non-zero (e.g., negative) V_{SG} for the first transistor 130. The resulting non-zero (e.g., negative) V_{SG} may reduce (compared to a positive V_{SG} or a V_{SG} of 0V) leakage current through the first transistor 130 of the second inverter 122 while the first transistor 130 is off. For example, the first transistor 130 of the second inverter 122 may correspond to a PMOS transistor, and application of the first voltage (e.g., 1.5V) to the gate terminal 131 of the first transistor 130 while the second voltage (e.g., 1.3V) is applied to the terminal 129 of the first transistor 130 may turn off the first transistor 130 and may result in a non-zero (e.g., negative) V_{SG} for the first transistor 130 corresponding to −0.2V (e.g., 1.3V-1.5V=−0.2V). The resulting non-zero (e.g., negative) V_{SG} (e.g., the V_{SG} of −0.2V) may reduce (compared to a positive V_{SG} or a V_{SG} of 0V) leakage current through the first transistor 130 of the second inverter 122 while the first transistor 130 is off. Thus, the first power gating circuit 108 may reduce standby leakage current through the first transistor 130 of the second inverter 122. Additionally, in contrast to conventional power gating where voltage at the transistors may float during the standby mode, the transistor states or conditions of transistors of the logic circuit 106 may be known or predictable (e.g., at a transition from standby mode to normal mode), enabling the logic circuit 106 to provide a particular output in response to a particular input.

Although the device 100 is illustrated as including a logic circuit 106 including three inverters having interleaved terminals (e.g., terminals 123, 127, and 129 are interleaved across the first power rail 102 and the second power rail 104 and terminals 145, 148, and 151 are interleaved across the first ground rail 132 and the second ground rail 133), other implementations of the logic circuit 106 may include more than or less than three inverters with interleaved terminals. Furthermore, although the device 100 is illustrated as including a second power rail 104, a second ground rail 133, and first and second power gating circuits 108 and 135, in other implementations, the device 100 may not include the second ground rail 133 and the second power gating circuit 135 or may not include the second power rail 104 and the first power gating circuit 108. For example, in other implementations, the device 100 may not include the second ground rail 133 and the second power gating circuit 135. In these implementations, the terminal 148 of the second transistor 146 may be coupled (e.g., directly) to the first ground rail 132. As another example, in other implementations, the device 100 may not include the second power rail 104 and the first power gating circuit 108. In these implementations, the terminal 123 of the first transistor 124 of the third inverter 118 and the terminal 129 of the first transistor 130 of the second inverter 122 may be coupled (e.g., directly) to the first power rail 102.

Referring to FIG. 2, a particular illustrative embodiment of a decoder device is disclosed and generally designated 200. The decoder device 200 includes a first power rail 202 and a second power rail 204. The first power rail 202 and the second power rail 204 may correspond to, or may be configured as described above with reference to, the first power rail 102 of FIG. 1 and the second power rail 104, respectively.

The decoder device 200 includes a first power gating circuit 208 including a switching device 210 connected between (e.g., electrically between) a unit address decoder 216 and a voltage source 201. The first power gating circuit 208 further includes a clamping diode 212 connected in parallel to the switching device 210 between (e.g., electrically between) the unit address decoder 216 and the voltage source 201. In some examples, the switching device 210 may be connected in parallel to the clamping diode 212 between (e.g., electrically between) the first power rail 202 and the second power rail 204. In some examples, the switching device 210 includes a p-type metal oxide semiconductor (PMOS) transistor. The first power gating circuit 208 further includes a clamping diode connected in parallel (e.g., electrical parallel) to the switching device 210 between (e.g., electrically between) the first power rail 202 and the second power rail 204. For example, an input of the clamping diode 212 and a source terminal or a drain terminal of the switching device 210 may be connected to the first power rail 202, and a source or a drain terminal of the switching device 210 and an output of the clamping diode 212 may be connected to the second power rail 204. In some examples, the clamping diode 212 may correspond to or may include a PMOS transistor (e.g., a “diode-connected PMOS transistor”). In some examples, the diode-connected PMOS transistor may include a drain terminal and a gate terminal coupled to the second power rail 204 and a source terminal coupled to the first power rail 202.

In some examples, such as when the unit address decoder 216 is in a first operating mode (e.g., a non-power saving mode), the switching device 210 may be closed and a voltage (e.g., a “first voltage”) from the first power rail 202 may be supplied (e.g., across the switching device 210) to the second power rail 204 such that a voltage (e.g., a “second voltage”) of the second power rail 204 corresponds to (e.g., is substantially equal to) the first voltage of the first power rail 202. In other examples, such as when the unit address decoder 216 is in a second operating mode (e.g., a power saving mode), the switching device 210 may be open and only a portion of the first voltage from the first power rail 202 is supplied to the second power rail 204 such that the second voltage of the second power rail 204 corresponds to a voltage that is different (e.g., substantially different) than (e.g., less than) the first voltage of the first power rail 202. In some examples, the second voltage may correspond to the first voltage (e.g., Vdd) from the first power rail 202 minus a threshold voltage of the clamping diode 212.

For example, during operation in the non-power saving mode, the switching device 210 may be closed, thereby short-circuiting the first power rail 202 to the second power rail 204 (causing the first voltage from the first power rail 202 to be applied across the switching device 210 to the second power rail 204). Thus, second voltage of the second power rail 204 may correspond to (e.g., may be substantially equal to) the first voltage of the first power rail 202 during the non-power saving mode. During the power saving mode, a signal that opens (e.g., turns off) the switching device 210 may be applied to the switching device 210 via a control 211. Opening the switching device 210 may cause leakage current to discharge the voltage at the second power rail 204 to a voltage (e.g., the second voltage) that causes the clamping diode 212 to turn on, thereby clamping the voltage at the second power rail 204 at a different (e.g., a substantially different) voltage than the first voltage. To illustrate, the first voltage may correspond to 1.5V, and the threshold voltage of the clamping diode 212 may correspond to 0.2V. In this example, when the switching device 210 is open (e.g., off), the second power rail 204 may discharge to 1.3V, at which point the clamping diode 212 may turn on and may clamp the second voltage of the second power rail 204 to 1.3V (e.g., 1.5V-0.2V=1.3 V).

As described above, in some examples, the switching device 210 may correspond to or may include a PMOS transistor, and the clamping diode 212 may correspond to or may include the diode-connected PMOS transistor. In these examples, during the power saving mode, the switching device 210 is off and in a floating state, which causes the second power rail 204 to discharge (e.g., causing the voltage at the second power rail 204 to drop and causing a potential difference between the first power rail 202 and the second power rail 204 to increase). The voltage at the second power rail 204 may drop until the voltage difference between the first power rail 202 and the second power rail 204 (e.g., the source-to-drain voltage V_{SD} of the diode-connected PMOS transistor) corresponds to the threshold voltage of the diode-connected PMOS transistor. When the V_{SD} of the diode-connected PMOS transistor corresponds to the threshold voltage of the diode-connected PMOS transistor, the diode-connected PMOS transistor may turn on, causing the second voltage of the second power rail 204 to correspond to the first voltage of the first power rail 202 minus the threshold voltage of the diode-connected PMOS transistor.

Thus, the second voltage of the second power rail 204 may be derived from the first voltage of the first power rail 202 and may vary based on the first power gating circuit 208 (e.g., based on whether the switching device 210 is open or closed), which may be controlled (e.g., by the control 211) based on an operating mode of the unit address decoder 216.

The decoder device 200 includes a first ground rail 232 and a second ground rail 233. The first ground rail 232 and the second ground rail 233 may correspond to, or be configured as described above with reference to, the first ground rail 132 of FIG. 1 and the second ground rail 133, respectively. In some examples, the first ground rail 232 may be coupled (e.g., directly coupled) to ground 259 and a voltage (e.g., a “third voltage”) of the first ground rail 232 may correspond to ground.

The decoder device 200 includes a second power gating circuit 235 including a switching device 236 connected between (e.g., electrically between) the first ground rail 232 and the second ground rail 233. In some examples, the switching device 236 includes an n-type metal oxide semiconductor (NMOS) transistor. The second power gating circuit 235 further includes a clamping diode 234 connected in parallel (e.g., electrical parallel) to the switching device 236 between (e.g., electrically between) the first ground rail 232 and the second ground rail 233. For example, an input of the clamping diode 234 and a source or a drain terminal of the switching device 236 may be connected to the first ground rail 232, and a source or a drain terminal of the switching device 236 and an output of the clamping diode 234 may be connected to the second ground rail 233. In some examples, the clamping diode 234 may correspond to or may include an NMOS transistor (e.g., a “diode-connected NMOS transistor”). In some examples, the diode-connected NMOS transistor may include a drain terminal and a gate terminal coupled to the second ground rail 233 and a source terminal coupled to the first ground rail 232.

In some examples, such as when the unit address decoder 216 is in the first operating mode (e.g., a non-power saving mode), the switching device 236 may be closed and a voltage (e.g., a “third voltage”) from the first ground rail 232 may be supplied (e.g., across the switching device 236) to the second ground rail 233 such that a voltage (e.g., a “fourth voltage”) of the second ground rail 233 corresponds to (e.g., is substantially equal to) the third voltage of the first ground rail 232. In other examples, such as when the unit address decoder 216 is in the second operating mode, the switching device 236 may be open and the fourth voltage of the second ground rail 233 may correspond to a voltage that is different (e.g., substantially different) than (e.g., greater than) the third voltage of the first ground rail 232, as described in more detail below. In some examples, the fourth voltage may correspond to the third voltage (e.g., Vss) from the first ground rail 232 plus a threshold voltage of the clamping diode 234.

For example, during operation in the non-power saving mode, the switching device 236 may be closed, thereby short-circuiting the first ground rail 232 to the second ground rail 233 (causing the third voltage from the first ground rail 232 to be applied across the switching device 236 to the second ground rail 233). Thus, the fourth voltage of the second ground rail 233 may correspond to (e.g., may be substantially equal to) the third voltage of the first ground rail 232 during the non-power saving mode. During the power saving mode, a signal that opens (e.g., turns off) the switching device 236 may be applied to the switching device 236 via a control 213. Opening the switching device 236 may cause leakage current to charge the voltage at the second ground rail 233 to a voltage (e.g., to the fourth voltage) that causes the clamping diode 234 to turn on, thereby clamping the voltage at the second ground rail 233 to a different (e.g., a substantially different) voltage than the third voltage. To illustrate, the third voltage may correspond to 0V, and the threshold voltage of the clamping diode 234 may correspond to 0.2V. In this example, when the switching device 236 is open (e.g., off), the second ground rail 233 may charge to 0.2V, at which point the clamping diode 234 may turn on and may clamp the fourth voltage of the second ground rail 233 to the 0.2V (e.g., 0V+0.2V=0.2 V).

As described above, in some examples, the switching device 236 may correspond to or may include an NMOS transistor, and the clamping diode 234 may correspond to or may include the diode-connected NMOS transistor. In these examples, during the power saving mode, the switching device 236 is off and in a floating state, which causes the second ground rail 233 to charge (e.g., causing the voltage at the second ground rail 233 to increase and causing a potential difference between the first ground rail 232 and the second ground rail 233 to increase). The voltage at the second ground rail 233 may increase until the voltage difference between the first ground rail 232 and the second ground rail 233 (e.g., the drain-to-source voltage V_{DS} of the diode-connected NMOS transistor) corresponds to the threshold voltage of the diode-connected NMOS transistor. When the V_{DS} of the diode-connected NMOS transistor corresponds to the threshold voltage of the diode-connected NMOS transistor, the diode-connected NMOS transistor may turn on, causing the fourth voltage of the second ground rail 233 to correspond to the third voltage of the first ground rail 232 minus the threshold voltage of the diode-connected NMOS transistor.

Thus, the fourth voltage of the second ground rail 233 may be derived from the third voltage of the first ground rail 232 and may vary based on the second power gating circuit 235 (e.g., based on whether the switching device 236 is open or closed), which may be controlled (e.g., by the control 213) based on an operating mode of the unit address decoder 216.

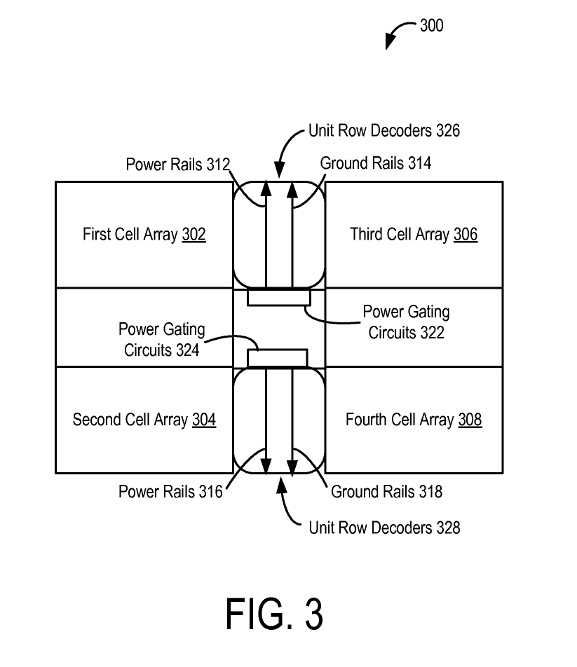

The decoder device 200 includes a unit address decoder 216. The unit address decoder 216 may correspond to a unit row decoder or a unit column decoder. For example, the unit address decoder 216 may correspond to a unit row decoder of a group of unit row decoders that is collectively used to access rows of a cell (e.g., a memory cell) array (such as one or more of cell (e.g., memory cell) arrays 302, 304, 306, or 308 of FIG. 3) that includes multiple rows. Each unit row decoder of the group of unit row decoders may be configured to access a particular (e.g., an associated) row of the multiple rows. As an example, the cell array may include 256 rows, the group of unit row decoders may include 256 unit row decoders, and each of the 256 unit row decoders of the collective decoder set may be associated with a particular row of the 256 rows of the cell array. In this example, an upstream pre-decoder may receive an address that includes bits corresponding to a particular row address of the cell array. For example, the pre-decoder may receive an eight bit memory address corresponding to a particular row address of the cell array. The pre-decoder may be configured to output signals (e.g., RAi and RAj signals) corresponding to the particular unit row decoder associated with the row indicated by the eight bit memory address.

To illustrate, the unit address decoder 216 may be associated with the 98^{th} row of the cell array and may be activated when the pre-decoder outputs an RAi=2 signal and an RAj=6 signal (e.g., RAi and RAj signals associated with the 98^{th} row of the cell array). In this example, the pre-decoder may receive a row address corresponding to the 98^{th} row of the cell array (e.g., 01100010 corresponding to 98 in binary) and the pre-decoder may determine that the first four bits 0010 (corresponding to 2 in binary) correspond to a second RAi line or output signal (e.g., RAi=2) and the second four bits 0110 (corresponding to 6 in binary) correspond to a sixth RAj line or output signal (e.g., RAj=6). The pre-decoder may output the RAi=2 and RAj=6 signals, thereby activating the unit address decoder 216 (having input lines RAi=2 and RAj=6 and associated with the 98^{th} row of the cell array).

The unit address decoder 216 includes an address decoder circuit 206. The address decoder circuit 206 may include logic gates 231 coupled to corresponding input lines RAi and RAj and coupled to the first power rail 202. The address decoder circuit 206 may also include logic gates 237 coupled to corresponding input lines RAi and RAj and coupled to the second ground rail 233. In some examples, the logic gates 231 may include a PMOS transistor P0 having a gate terminal coupled to RAj and may include a PMOS transistor P1 having a gate terminal coupled to RAi. The PMOS transistors P0 and P1 may each include a source terminal or a drain terminal coupled to the first power rail 202. As another example, the logic gates 237 may include an NMOS transistor N0 having a gate terminal coupled to RAi and an NMOS transistor N1 having a gate terminal coupled to RAj. The NMOS transistor N0 may have a source terminal or a drain terminal coupled to a source terminal or a drain terminal of the NMOS transistor N1, and the NMOS transistor N1 may have a source terminal or a drain terminal coupled to the second ground rail 233.

The address decoder circuit 206 may include a third inverter 218 having an input coupled to an output of the logic gates 231 and the logic gates 237. The third inverter 218 may include a first transistor 224 having a terminal 223 (e.g., a source terminal or a drain terminal) coupled (e.g., directly) to the second power rail 204 and may include a second transistor 244 having a terminal 245 (e.g., a source terminal or a drain terminal) coupled (e.g., directly) to the first ground rail 232. In some examples, the first transistor 224 of the third inverter 218 may correspond to a PMOS transistor and the second transistor 244 of the third inverter 218 may correspond to an NMOS transistor.

The unit address decoder 216 also includes a driver circuit 209 that includes a first inverter 220 and a second inverter 222. The first inverter 220 may include a first transistor 226 and a second transistor 246. The second inverter 222 may include a first transistor 230 and a second transistor 250. In some examples, the first transistor 226 of the first inverter 220, the first transistor 230 of the second inverter 222, or both, include a PMOS transistor. Additionally or alternatively, in some examples, the second transistor 246 of the first inverter 220, the second transistor 250 of the second inverter 222, or both, include an NMOS transistor.

A terminal 227 (e.g., a source terminal or a drain terminal) of the first transistor 226 of the first inverter 220 may be coupled (e.g., directly) to the first power rail 202. Additionally or alternatively, a terminal 229 (e.g., a source terminal or a drain terminal) of the first transistor 230 of the second inverter 222 may be coupled (e.g., directly) to the second power rail 204. A terminal 248 (e.g., a source terminal or a drain terminal) of the second transistor 246 of the first inverter 220 may be coupled (e.g., directly) to the second ground rail 233. Additionally or alternatively, a terminal 251 (e.g., a source terminal or a drain terminal) of the second transistor 250 of the second inverter 222 may be coupled (e.g., directly) to the first ground rail 232.

During operation in a power saving mode, the signals RAi and RAj may correspond to 0V, and the source terminals or the drain terminals of the logic gates 231 may receive the first voltage. Application of 0V to the gate terminals of the logic gates 231 while the drain terminals or the source terminals of the logic gates 231 are coupled to the first power rail 202 (e.g., while the first voltage is applied to the drain terminals or the source terminals of the logic gates 231) may turn on the logic gates 231. For example, the logic gates 231 may correspond to the PMOS transistors P0 and P1 and application of the first voltage to the drain terminals or the source terminals of the logic gates 231 while RAi and RAj correspond to 0V may turn on the PMOS transistors P0 and P1. Additionally, application of 0V to gate terminals of the logic gates 237 may turn off the logic gates 237. For example, the logic gates 237 may correspond to the NMOS transistors N0 and N1 and application of 0V to the terminals of the NMOS transistors N0 and N1 may turn off the NMOS transistors N0 and N1. Thus, as the logic gates 237 are off during operation in the power saving mode, the first voltage from the first power rail 202 is passed through one or more of the logic gates 231 and output to the third inverter 218.

During operation in the power saving mode, the terminal 223 of the first transistor 224 of third inverter 218 may receive the second voltage (that is different from the first voltage as described above) from the second power rail 204 and the terminal 245 of the second transistor 244 of the third inverter 218 may receive the third voltage (e.g., a ground voltage) from the first ground rail 232. Application of the first voltage (from the first power rail 202 passed through one or more of the logic gates 231) to the input of the third inverter 218 while the third voltage is applied to the terminal 245 of the second transistor 244 of the third inverter 218 may cause the second transistor 244 to turn on. For example, the second transistor 244 of the third inverter 218 may correspond to an NMOS transistor, and application of the first voltage (e.g., 1.5V) to the gate terminal 243 of the second transistor 244 while the third voltage (e.g., ground) is applied to the terminal 245 of the second transistor 244 may turn on the second transistor 244.

Additionally or alternatively, application of the first voltage (from the first power rail 202 passed through one or more of the logic gates 231) to the input of the third inverter 218 while the switching device 210 is off and the second voltage (that is different than the first voltage as described above) is applied to the terminal 223 of the first transistor 224 of the third inverter 218 may result in a non-zero (e.g., negative) source to gate voltage (V_{SG}) for the first transistor 224 that is not sufficient to turn on the first transistor 224 of the third inverter 218 (e.g., the first transistor 224 may be off). The resulting non-zero (e.g., negative) V_{SG} may reduce (compared to a positive V_{SG} or a V_{SG} of 0V) leakage current through the first transistor 224 of the third inverter 218 while the first transistor 224 is off. For example, the first transistor 224 of the third inverter 218 may correspond to a PMOS transistor, and application of the first voltage (e.g., 1.5V) to the gate terminal 225 of the first transistor 224 while the second voltage (e.g., 1.3V) is applied to the terminal 223 of the first transistor 224 may turn off the first transistor 224 and may result in a non-zero (e.g., negative) V_{SG} for the first transistor 224 that corresponds to the second voltage minus the first voltage (e.g., 1.3V-1.5V=−0.2V). The resulting non-zero (e.g., negative) V_{SG} (e.g., the V_{SG} of −0.2V) may reduce (compared to a positive V_{SG} or a V_{SG} of 0V) leakage current through the first transistor 224 of the third inverter 218 while the first transistor 224 is off Thus, the first power gating circuit 208 may reduce standby leakage current through the first transistor 224 of the third inverter 218.

During operation in the power saving mode, the terminal 227 of the first transistor 226 of the first inverter 220 may receive the first voltage from the first power rail 202, and the terminal 248 of the second transistor 246 of the first inverter 220 may receive the fourth voltage from the second ground rail 233. Turning off the first transistor 224 of the third inverter 218 and turning on the second transistor 244 of the third inverter 218 as described above may cause an output of the third inverter 218 to correspond to the third voltage (e.g., ground voltage). Thus, a voltage corresponding to ground may be applied to the input of the first inverter 220.

Application of the ground voltage to the input of the first inverter 220 while the first voltage from the first power rail 202 is applied to the terminal 227 of the first transistor 226 of the first inverter 220 may turn on the first transistor 226. For example, the first transistor 226 of the first inverter 220 may correspond to a PMOS transistor, and application of ground to a gate terminal 228 of the first transistor 226 while the first voltage (e.g., 1.5V) is being applied to the terminal 227 of the first transistor 226 may turn on the first transistor 226.

Application of the ground voltage to the input of the first inverter 220 may prevent the second transistor 246 of the first inverter 220 from turning on and may result in a non-zero (e.g., negative) V_{GS} for the second transistor 246. The resulting non-zero (e.g., negative) V_{GS} may reduce (compared to a positive V_{GS} or a V_{GS} of 0V) leakage current through the second transistor 246 of the first inverter 220 while the second transistor 246 is off. For example, the second transistor 246 of the first inverter 220 may correspond to an NMOS transistor, and application of the ground voltage to the gate terminal 247 of the second transistor 246 while the third voltage (e.g., 0.2V) from the second ground rail 233 is applied to the terminal 248 of the second transistor 246 may prevent the second transistor 246 from turning on and may result in a V_{GS} of −0.2V (e.g., 0V−0.2V=−0.2V) for the second transistor 246. The non-zero (e.g., negative) V_{GS} e.g., (the V_{GS} of −0.2V) of the second transistor 246 of the first inverter 220 may reduce (compared to a positive V_{GS} or a V_{GS} of 0V) leakage current through the second transistor 246 while the second transistor 246 is off Thus, the second power gating circuit 235 may reduce standby leakage current through the second transistor 246 of the first inverter 220. Additionally, because the first transistor 226 is turned on and the second transistor 246 is turned off, the first inverter 220 may output (to the second inverter 222) the first voltage (passed from the first power rail 202 through the first transistor 226).

During operation in the power saving mode, the terminal 229 of the first transistor 230 of the second inverter 222 may receive the second voltage (that is different than the first voltage as described above) from the second power rail 204, and the terminal 251 of the second transistor 250 of the second inverter 222 may receive the third voltage from the first ground rail 232. Turning on the first transistor 226 of the first inverter 220 and turning off the second transistor 246 of the first inverter 220 as described above may cause an output of the first inverter 220 to correspond to the first voltage. Thus, the first voltage may be applied to the input of the second inverter 222.

Application of the first voltage to the input of the second inverter 222 while the third voltage from the first ground rail 232 is applied to the terminal 251 of the second transistor 250 of the second inverter 222 may turn on the second transistor 250. For example, the second transistor 250 of the second inverter 222 may correspond to an NMOS transistor, and application of the first voltage to a gate terminal 249 of the second transistor 250 while the third voltage (e.g., 0V) is being applied to the terminal 251 of the second transistor 250 may turn on the second transistor 250.

Application of the first voltage to the second inverter 222 while the switching device 210 is off and the second voltage (that is different than the first voltage as described above) is being applied to the terminal 229 of the first transistor 230 of the second inverter 222 may turn off the first transistor 230 and may result in a non-zero (e.g., negative) V_{SG} for the first transistor 230. The resulting non-zero (e.g., negative) V_{SG} may reduce (compared to a positive V_{SG} or a V_{SG} of 0V) leakage current through the first transistor 230 of the second inverter 222 while the first transistor 230 is off. For example, the first transistor 230 of the second inverter 222 may correspond to a PMOS transistor, and application of the first voltage (e.g., 1.5V) to a gate terminal 258 of the first transistor 230 while the second voltage (e.g., 1.3V) is applied to the terminal 229 of the first transistor 230 may turn off the first transistor 230 and may result in a non-zero (e.g., negative) V_{SG} for the first transistor 230 corresponding to −0.2V (e.g., 1.3V-1.5V=−0.2V). The resulting non-zero (e.g., negative) V_{SG} (e.g., the V_{SG} of −0.2V) may reduce (compared to a positive V_{SG} or a V_{SG} of 0V) leakage current through the first transistor 230 of the second inverter 222 while the first transistor 230 is off Thus, the first power gating circuit 208 may reduce standby leakage current through the first transistor 230 of the second inverter 222. Additionally, in contrast to conventional power gating where voltage at the transistors may be floated during the standby mode, the transistor states or conditions of transistors of the driver circuit 209 may be known or predictable (e.g., at a transition from standby mode to normal mode), enabling the unit address decoder 216 to provide a particular output at output 217 (e.g., 0V precharge condition) in response to a particular input.

Referring to FIG. 3, a particular illustrative embodiment of a memory device including unit row decoders sharing common power gating circuits is generally depicted as 300. The memory device 300 may include power rails 312, which include a first power rail and a second power rail, and power rails 316, which include a third power rail and a fourth power rail. The first and third power rails may correspond to power rails directly coupled to power/voltage sources. For example, the first and third power rails may be configured as described above with reference to the first power rail 102 of FIG. 1 or the first power rail 202 of FIG. 2. The first and third power rails may be configured to supply a voltage (e.g., a first voltage) as described above with reference to the first power rail 102 of FIG. 1 or the first power rail 202 of FIG. 2. The second and fourth power rails may correspond to power rails that derive voltage (e.g., a second voltage) from the first and third power rails, respectively. For example, the second and fourth power rails may be configured as described above with reference to the second power rail 104 of FIG. 1 or the second power rail 204 of FIG. 2 to derive the second voltage that corresponds to the first voltage or to derive the second voltage that is different than (e.g., less than) the first voltage.

The memory device 300 may include ground rails 314, which include a first ground rail and a second ground rail, and may include ground rails 318, which include a third ground rail and a fourth ground rail. The first and third ground rails may correspond to ground rails that are directly coupled to ground. For example, the first and third ground rails may be configured as described above with reference to the first ground rail 132 of FIG. 1 or the first ground rail 232 of FIG. 2. The first and third power rails may be configured to supply a voltage (e.g., a third voltage) as described above with reference to the first ground rail 132 of FIG. 1 or the first ground rail 232 of FIG. 2. The second and fourth ground rails may correspond to ground rails that derive voltage (e.g., a fourth voltage) from the first and third ground rails, respectively. For example, the second and fourth ground rails may be configured as described above with reference to the second ground rail 133 of FIG. 1 or the second ground rail 233 of FIG. 2 to derive the fourth voltage that corresponds to the third voltage or to derive the fourth voltage that is different than (e.g., greater than) the third voltage.

The memory device 300 may include unit row decoders 326 associated with rows of a first cell array 302 and/or with rows of a third cell array 306. Each unit row decoder of the unit row decoders 326 may be associated with a particular row of the first cell array 302 and/or the third cell array 306. Each unit row decoder of the unit row decoders 326 may have particular inputs (e.g., RAi and RAj inputs as described above with reference to FIG. 2) corresponding to the particular row of the first cell array 302 and/or the third cell array 306 that the unit row decoder is associated with. For example, a first unit row decoder of the unit row decoders 326 may include components configured as described above with reference to the unit address decoder 216 of FIG. 2 and may have particular inputs RAi=w and RAj=x, which may correspond to a P^{th} row of the multiple rows of the first cell array 302. As another example, a second unit row decoder of the unit row decoders 326 may include components configured as described above with reference to the unit address decoder 216 of FIG. 2 and may have particular inputs RAi=y and RAj=z, which may correspond to a Q^{th} row of the multiple rows of the third cell array 306.

The first unit row decoder of the unit row decoders 326 may be coupled to the first power rail and to the second power rail of the power rails 312 as described above with reference to the unit address decoder 216 of FIG. 2 and the first power rail 202 and the second power rail 204. To illustrate, the first unit row decoder of the unit row decoders 326 of FIG. 3 may include a first inverter corresponding to the first inverter 220 of FIG. 2 that includes a first transistor corresponding to the first transistor 226 coupled (e.g., directly) to the first power rail of the power rails 312 of FIG. 3. The first unit row decoder of the unit row decoders 326 may also include a second inverter corresponding to the second inverter 222 of FIG. 2 that includes a first transistor corresponding to the first transistor 230 coupled to the second power rail of the power rails 312 of FIG. 3. Thus, the first unit row decoder of the unit row decoders 326 may include inverters interleaved between the first and second power rails of the power rails 312.

As another example, the first unit row decoder of the unit row decoders 326 may be coupled to the first ground rail and the second ground rail of the ground rails 314 of FIG. 3 as described above with reference to the unit address decoder 216 of FIG. 2 and the first ground rail 232 and the second ground rail 233. To illustrate, the first inverter of the first unit row decoder may include a second transistor corresponding to the second transistor 246 coupled (e.g., directly) to the second ground rail of the ground rails 314 of FIG. 3. The second inverter corresponding of the first unit row decoder may also include a second transistor corresponding to the second transistor 250 coupled to the first ground rail of the ground rails 314 of FIG. 3. Thus, the first unit row decoder of the unit row decoders 326 may include inverters interleaved between the first and second ground rails of the ground rails 314.

The second unit row decoder of the unit row decoders 326 may be coupled to the first power rail and to the second power rail of the power rails 312 as described above with reference to the unit address decoder 216 of FIG. 2 and the first power rail 202 and the second power rail 204. To illustrate, the second unit row decoder of the unit row decoders 326 of FIG. 3 may include a first inverter corresponding to the first inverter 220 of FIG. 2 that includes a first transistor corresponding to the first transistor 226 coupled (e.g., directly) to the first power rail of the power rails 312 of FIG. 3. The second unit row decoder of the unit row decoders 326 may also include a second inverter corresponding to the second inverter 222 of FIG. 2 that includes a first transistor corresponding to the first transistor 230 coupled to the second power rail of the power rails 312 of FIG. 3. Thus, the second unit row decoder of the unit row decoders 326 may include inverters interleaved between the first and second power rails of the power rails 312.

As another example, the second unit row decoder of the unit row decoders 326 may be coupled to the first ground rail and the second ground rail of the ground rails 314 of FIG. 3 as described above with reference to the unit address decoder 216 of FIG. 2 and the first ground rail 232 and the second ground rail 233. To illustrate, the first inverter of the second unit row decoder of the unit row decoders 326 of FIG. 3 may include a second transistor corresponding to the second transistor 246 of FIG. 2 coupled (e.g., directly) to the second ground rail of the ground rails 314 of FIG. 3. The second inverter of the second unit row decoder of the unit row decoders 326 may also include a second transistor corresponding to the second transistor 250 of FIG. 2 coupled to the first ground rail of the ground rails 314 of FIG. 3. Thus, the second unit row decoder of the unit row decoders 326 may include inverters interleaved between the first and second ground rails of the ground rails 314.

Thus, multiple unit row decoders of the unit row decoders 326 may include inverters interleaved between the first and second power rails of the power rails 312. Additionally, the multiple row decoders of the unit row decoders 326 may include inverters interleaved between the first and second ground rails of the ground rails 314.

The memory device 300 may include power gating circuits 322. The power gating circuits 322 may include a first power gating circuit and a second power gating circuit. The first power gating circuit of the power gating circuits 322 may correspond to, or may be configured and/or may function as described above with reference to, the first power gating circuit 108 of FIG. 1 or the first power gating circuit 208 of FIG. 2. For example, the first power gating circuit of the power gating circuits 322 may include a first switching device (e.g., single transistor) corresponding to the switching device 210 of FIG. 2. The first power gating circuit of the power gating circuits 322 of FIG. 3 may also include a first clamping diode corresponding to the clamping diode 212 of FIG. 2 connected in parallel to the first switching device between the first power rail and the second power rail of the power rails 312 of FIG. 3. For example, when the first switching device of the first power gating circuit of the power gating circuits 322 is open, the first clamping diode of the power gating circuits may clamp the second power rail of the power rails 312 to the second voltage that is different than (e.g., less than) the first voltage. When the first switching device of the first power gating circuit of the power gating circuits 322 is closed, the first voltage from the first power rail of the power rails 312 may be applied across the first switching device to the second power rail of the power rails 312 (e.g., the second voltage of the second power rail may correspond to the first voltage). As described above, multiple row decoders of the unit row decoders 326 may include inverters that are interleaved between the first and second power rails of the power rails 312. Thus, the first power gating circuit of the power gating circuits 322 may function as a common power gating circuit for multiple unit row decoders of the unit row decoders 326.

The second power gating circuit of the power gating circuits 322 may correspond to, or may be configured and/or may function as described above with reference to, the second power gating circuit 135 of FIG. 1 or the second power gating circuit 235 of FIG. 2. For example, the second power gating circuit of the power gating circuits 322 may include a second switching device (e.g., a single transistor) corresponding to the switching device 236 of FIG. 2. The second power gating circuit of the power gating circuits 322 of FIG. 3 may also include a second clamping diode corresponding to the clamping diode 234 of FIG. 2 connected in parallel to the second switching device between the first ground rail and the second ground rail of the ground rails 314 of FIG. 3. For example, when the second switching device of the second power gating circuit of the power gating circuits 322 is open, the second clamping diode of the second power gating circuit may clamp the second ground rail of the ground rails 314 to the fourth voltage that is different than (e.g., greater than) the third voltage. When the second switching device of the second power gating circuit of the power gating circuits 322 is closed, the third voltage from the first ground rail of the ground rails 314 may be applied across the second switching device to the second ground rail of the ground rails 314 (e.g., the fourth voltage of the second ground rail may correspond to the third voltage). As described above, multiple unit row decoders of the unit row decoders 326 may include inverters that are interleaved between the first and second ground rails of the ground rails 314. Thus, the second power gating circuit of the power gating circuits 322 may function as a common power gating circuit for multiple unit row decoders of the unit row decoders 326.

Thus, the multiple unit row decoders 326 may be power gated using a first common power gating circuit (e.g., using a single power gating switch transistor), thereby reducing chip area relative to architectures that employ non-common power gating switches (e.g., architectures that employ a power gating switch for each unit row decoder). Additionally or alternatively, the multiple unit row decoders 326 may be ground gated using a second common power gating circuit (e.g., using a single power gating switch transistor), thereby reducing chip area relative to architectures that employ non-common power gating switches (e.g., architectures that employ a power gating switch for each unit row decoder).

The memory device 300 may include unit row decoders 328 associated with rows of a second cell array 304 and/or with rows of a fourth cell array 308. Each unit row decoder of the unit row decoders 328 may be associated with a particular row of the second cell array 304 and/or the fourth cell array 308. Each unit row decoder of the unit row decoders 328 may include inverters interleaved between the third power rail and the fourth power rail of the power rails 316 as described above with reference to the first power rail and the second power rail of the power rails 312. Additionally or alternatively, each unit row decoder of the unit row decoders 328 may include inverters interleaved between the third ground rail and the fourth ground rail of the ground rails 318 as described above with reference to the first and second ground rails of the ground rails 314.

The memory device 300 may include power gating circuits 324. The power gating circuits 324 may include a first power gating circuit configured to control a voltage applied to the fourth power rail of the power rails 316 as described above with reference to the first power gating circuit of the power gating circuits 322 and the second power rail of the power rails 312. The power gating circuits 324 may include a second power gating circuit configured to control a voltage applied to the fourth ground rail of the ground rails 318 as described above with reference to the second power gating circuit of the power gating circuits 322 and the second ground rail of the ground rails 314.

Thus, the multiple unit row decoders 328 may be power gated using a first common power gating circuit (e.g., using a single power gating switch transistor) to power gate a power supply, thereby reducing chip area relative to architectures that employ non-common power gating switches (e.g., that employ a power gating switch for each unit row decoder). Additionally or alternatively, the multiple unit row decoders 328 may be ground gated using a second common power gating circuit (e.g., using a single power gating switch transistor) to ground gate a ground supply, thereby reducing chip area relative to architectures that employ non-common power gating switches (e.g., that employ a power gating switch for each unit row decoder).

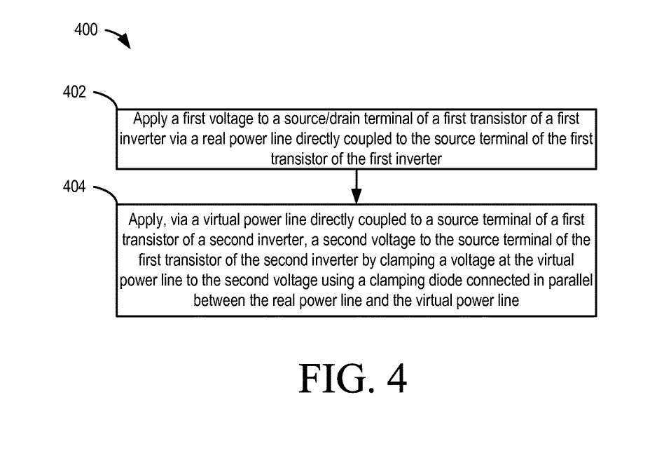

Referring to FIG. 4, a flow chart of an illustrative example of a method 400 of power gating a circuit is depicted. The method 400 may be performed using the device 100 of FIG. 1 or the decoder device 200 of FIG. 2.

The method 400 includes applying, at 402, a first voltage to a source/drain terminal of a first transistor of a first inverter via a first power rail directly coupled to the source/drain terminal of the first transistor of the first inverter. The first inverter may correspond to the first inverter 120 or 220 of FIG. 1 or 2, the first transistor may correspond to the first transistor 126 or 226 of FIG. 1 or 2, the first power rail may correspond to the first power rail 102 or 202 of FIG. 1 or 2, and the source/drain terminal may correspond to the terminal 127 or 227 of FIG. 1 or 2.

The method 400 further includes applying, via a second power rail directly coupled to a source/drain terminal of a first transistor of a second inverter, a second voltage to the source/drain terminal of the first transistor of the second inverter by clamping a voltage at the second power rail to the second voltage using a clamping diode connected in parallel between the first power rail and the second power rail. The second inverter may correspond to the second inverter 122 or 222 of FIG. 1 or 2, the first transistor may correspond to the first transistor 130 or 230, the second power rail may correspond to the second power rail 104 or 204, the source/drain terminal may correspond to the terminal 129 or 229, and the clamping diode may correspond to the clamping diode 112 or 212. The second voltage may be derived from a first voltage applied to the first power rail as described above. In some examples, the second voltage may correspond to the first voltage minus a threshold voltage of the clamping diode as described above. Thus, the method 400 includes interleaving inverters between a first power rail and a second power rail that derives voltage from the first power rail.

In some examples, the method 400 may further include turning off the first transistor of the second inverter during a first power mode by applying the first voltage to a gate terminal of the first transistor of the second inverter while applying the second voltage to the source/drain terminal of the first transistor of the second inverter. The gate terminal may correspond to the gate terminal 131 or 258 of FIG. 1 or 2, and the first power mode may correspond to a power saving mode as described above. In some examples, as described above, applying the first voltage to the gate terminal of the first transistor of the second inverter and applying the second voltage to the source/drain terminal of the first transistor of the second inverter may result in a non-zero (e.g., negative) V_{SG} that reduces (e.g., compared to positive V_{SG} a V_{SG} of 0V) sub-threshold leakage through the first transistor of the second inverter as described above. Thus, the method 400 may reduce sub-threshold leakage current of some transistors of a circuit when the circuit is in a power saving mode.

In some examples, the method 400 may further include turning on the first transistor of the first inverter during the first power mode by applying a third voltage to a gate terminal of the first transistor of the first inverter while applying the first voltage to the source/drain terminal of the first transistor of the first inverter. The gate terminal of the first transistor of the first inverter may correspond to the gate terminal 128 or 228 of FIG. 1 or 2. In some examples, the third voltage may be approximately zero (0) volts.

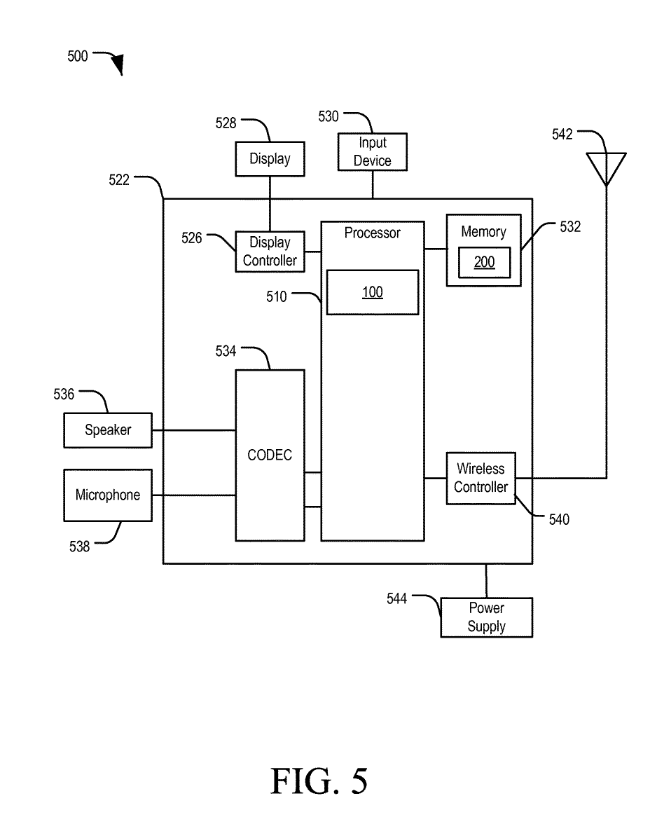

Referring to FIG. 5, a block diagram of a particular illustrative embodiment of a wireless communication device is depicted and generally designated 500. The device 500 includes a processor 510, such as a digital signal processor (DSP), coupled to a memory 532. In an illustrative embodiment, the processor 510 may include the device 100 of FIG. 1 and/or the memory 532 may include the decoder device 200 of FIG. 2 or the memory device 300 of FIG. 3. In an illustrative embodiment, the device 100 of FIG. 1 or the decoder device 200 of FIG. 2 may operate according to the method of FIG. 4. In some examples, the processor 510 may send a memory address (e.g., via a pre-decoder) to the device 100, and the device 100 may decode the memory address using power gated inverters as described above with reference to the device 100 of FIG. 1 or the decoder device 200 of FIG. 2.

FIG. 5 also shows a display controller 526 that is coupled to the processor 510 and to a display 528. A coder/decoder (CODEC) 534 can also be coupled to the processor 510. A speaker 536 and a microphone 538 can be coupled to the CODEC 534.

FIG. 5 also indicates that a wireless controller 540 can be coupled to the processor 510 and to a wireless antenna 542. In a particular embodiment, the processor 510, the display controller 526, the memory 532, the CODEC 534, and the wireless controller 540 are included in a system-in-package or system-on-chip device 522. In a particular embodiment, an input device 530 and a power supply 544 are coupled to the system-on-chip device 522. Moreover, in a particular embodiment, as illustrated in FIG. 5, the display 528, the input device 530, the speaker 536, the microphone 538, the wireless antenna 542, and the power supply 544 are external to the system-on-chip device 522. However, each of the display 528, the input device 530, the speaker 536, the microphone 538, the wireless antenna 542, and the power supply 544 can be coupled to a component of the system-on-chip device 522, such as an interface or a controller.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. A device comprising:
a first power rail;
a second power rail, wherein a second voltage of the second power rail is derived from a first voltage of the first power rail;
a power gating circuit comprising a switching device connected between the first power rail and the second power rail, the power gating circuit further comprising a clamping diode connected in parallel to the switching device between the first power rail and the second power rail; and
a logic circuit including a first inverter and a second inverter, the first inverter including a first transistor of the first inverter and the second inverter including a first transistor of the second inverter, wherein a source/drain terminal of the first transistor of the first inverter is directly coupled to the first power rail, and wherein a source/drain terminal of the first transistor of the second inverter is directly coupled to the second power rail.

2. The device of claim 1, further comprising:
a second transistor of the first inverter;
a second transistor of the second inverter;
a first ground rail; and
a second ground rail, wherein a fourth voltage of the second ground rail is derived from a third voltage of the first ground rail,
wherein a source/drain terminal of the second transistor of the first inverter is directly coupled to the second ground rail, and
wherein a source/drain terminal of the second transistor of the second inverter is directly coupled to the first ground rail.

3. The device of claim 2, further comprising a second power gating circuit comprising a second switching device connected between the first ground rail and the second ground rail, the second power gating circuit further comprising a second clamping diode connected in parallel to the second switching device between the first ground rail and the second ground rail.

4. The device of claim 3, wherein the second switching device includes an n-type metal oxide semiconductor (NMOS) transistor.

5. The device of claim 2, wherein the third voltage corresponds to ground, and the fourth voltage is greater than the third voltage.

6. The device of claim 1, wherein the logic circuit includes a unit address decoder that includes an address decoder circuit, and wherein the address decoder circuit includes a first transistor coupled to the first power rail and a second transistor coupled to the second power rail.

7. The device of claim 6, wherein the unit address decoder includes a unit row decoder, a unit column decoder, or both.

8. The device of claim 1, wherein, when the switching device is open, the clamping diode is configured to clamp a voltage at the second power rail to the second voltage, wherein the second voltage corresponds to the first voltage minus a threshold voltage of the clamping diode.

9. The device of claim 8, wherein when the switching device is closed, the second voltage corresponds to the first voltage.

10. The device of claim 1, wherein the first transistor of the second inverter is a p-type metal oxide semiconductor (PMOS) transistor, the first transistor of the first inverter is an n-type metal oxide semiconductor (NMOS) transistor, or both.

11. The device of claim 1, wherein the switching device includes a p-type metal oxide semiconductor (PMOS) transistor.

12. A decoder device comprising:
a unit address decoder including an address decoder circuit that includes a first transistor and a second transistor; and
a power gating circuit comprising a switching device connected between the unit address decoder and a voltage source, the power gating circuit further comprising a clamping diode connected in parallel to the switching device between the unit address decoder and the voltage source, wherein the first transistor of the address decoder circuit is coupled to a first terminal of the clamping diode, and wherein the second transistor is coupled to a second terminal of the clamping diode.

13. The decoder device of claim 12, wherein the unit address decoder includes a unit row decoder, a unit column decoder, or both.

14. The decoder device of claim 12, wherein the unit address decoder further includes a driver circuit, and wherein the power gating circuit is coupled to the driver circuit.

15. The decoder device of claim 14, further comprising:
a first power rail; and
a second power rail, wherein a second voltage of the second power rail is derived from a first voltage of the first power rail,
wherein the switching device is connected between the first power rail and the second power rail,
wherein the clamping diode is connected in parallel to the switching device between the first power rail and the second power rail, and
wherein the driver circuit comprises a first transistor of a first inverter and a first transistor of a second inverter, wherein a source/drain terminal of the first transistor of the first inverter is directly coupled the first power rail and a source/drain terminal of the first transistor of the second inverter is directly coupled to the second power rail.

16. The decoder device of claim 15, wherein the first transistor of the second inverter is a p-type metal oxide semiconductor (PMOS) transistor, the first transistor of the first inverter is an n-type metal oxide semiconductor (NMOS) transistor, or both.

17. The decoder device of claim 15, further comprising:
a first ground rail coupled to ground; and
a second ground rail, wherein a fourth voltage of the second ground rail is derived from a third voltage of the first ground rail,
wherein the driver circuit further comprises a second transistor of the first inverter and a second transistor of the second inverter, and wherein a source/drain terminal of the second transistor of the first inverter is directly coupled to the second ground rail and a source/drain terminal of the second transistor of the second inverter is directly coupled to the first ground rail.

18. The decoder device of claim 17, wherein the third voltage corresponds to ground and the fourth voltage is greater than the third voltage.

19. The decoder device of claim 15, wherein, when the switching device is open, the clamping diode is configured to clamp a voltage at the second power rail to the second voltage, wherein the second voltage corresponds to the first voltage minus a threshold voltage of the clamping diode.

20. The decoder device of claim 19, wherein, when the switching device is closed, the second voltage corresponds to the first voltage.

21. A method of power gating a circuit, the method comprising:
applying a first voltage to a source/drain terminal of a first transistor of a first inverter via a first power rail directly coupled to the source/drain terminal of the first transistor of the first inverter; and
applying, via a second power rail directly coupled to a source/drain terminal of a first transistor of a second inverter, a second voltage to the source/drain terminal of the first transistor of the second inverter by clamping a voltage at the second power rail to the second voltage using a clamping diode connected between the first power rail and the second power rail, the second voltage derived from a first voltage applied to the first power rail.

22. The method of claim 21, wherein the second voltage corresponds to the first voltage minus a threshold voltage of the clamping diode.

23. The method of claim 21, further comprising turning off the first transistor of the second inverter during a first power mode by applying the first voltage to a gate terminal of the first transistor of the second inverter while applying the second voltage to the source/drain terminal of the first transistor of the second inverter.

24. The method of claim 23, further comprising turning on the first transistor of the first inverter during the first power mode by applying a third voltage to a gate terminal of the first transistor of the first inverter while applying the first voltage to the source/drain terminal of the first transistor of the first inverter.

25. The method of claim 24, wherein the third voltage is approximately zero (0) volts.

26. A device comprising:
a first ground rail;
a second ground rail, wherein a second voltage of the second ground rail is derived from a first voltage of the first ground rail;
a first power rail;
a second power rail;
a power gating circuit comprising a switching device connected between the first ground rail and the second ground rail, the power gating circuit further comprising a clamping diode connected in parallel to the switching device between the first power rail and the second power rail; and
a logic circuit including a first inverter and a second inverter, the first inverter including a transistor and the second inverter including a transistor, wherein a source/drain terminal of the transistor of the first inverter is directly coupled to the second ground rail, and wherein a source/drain terminal of the transistor of the second inverter is directly coupled to the first ground rail.

27. The device of claim 26, wherein the logic circuit includes a unit address decoder that includes an address decoder circuit, wherein the address decoder circuit includes a first transistor coupled to the first ground rail and a second transistor coupled to the second ground rail.

28. The device of claim 27, wherein the unit address decoder includes a unit row decoder, a unit column decoder, or both.

29. The device of claim 26, wherein, when the switching device is open, the clamping diode is configured to clamp a voltage at the second ground rail to the second voltage, wherein the second voltage corresponds to the first voltage plus a threshold voltage of the clamping diode.

30. The device of claim 26, wherein when the switching device is closed, the second voltage corresponds to the first voltage.
